(19) United States
(12) Patent Application Publication
(10) Pub. No.: US 2010/0133850 A1
(43) Pub. Date: Jun. 3, 2010

(54) WIND AND SOLAR POWERED BILLBOARDS AND FIXTURES, AND METHODS OF USING AND FABRICATING THE SAME

(76) Inventor: Marvin Winkler, Los Angeles, CA (US)

Correspondence Address: GREENBERG TRAURIG LLP (LA), 2450 COLORADO AVENUE, SUITE 400E, INTELLECTUAL PROPERTY DEPARTMENT, SANTA MONICA, CA, 90404, US

(21) Appl. No.: 12/578,524

(22) Filed: Oct. 13, 2009

Related U.S. Application Data
(60) Provisional application No. 61/119,092, filed on Dec. 2, 2008.

(51) Int. Cl. F03D 9/00; H01L 31/042; G09F 13/02; G09F 7/00; G03B 21/00

(52) U.S. Cl. 290/55; 290/50; 136/244; 40/559; 40/584; 353/28

(57) ABSTRACT

Systems and methods for electric power generation are provided. The systems may include a wind turbine electric generator, a fixture, a battery, a processor, and a power grid. The wind turbine electric generator having a wind rotor, a plurality of blades and an electric generator. An image may be displayed on the blades to generate a dynamic image effect with the rotation of the blades around a central axis of rotation. The electric generator may be coupled to and driven by the wind rotor to generate an electrical current. The processor may be coupled to the wind turbine electric generator, the fixture, the battery, and the grid, and configured to transmit a first fraction of the electrical current to the fixture, transmit a second fraction of the electrical current to the battery, and transmit a third fraction of the electrical current to the grid.

### RELATED APPLICATION

This application claims the benefit of and priority to U.S. patent application Ser. No. 12/483,581, filed Jun. 12, 2009, which claims the benefit of and priority to U.S. Provisional Application Ser. No. 61/119,092, filed Dec. 2, 2008, the contents of which each are incorporated by reference herein in its entirety.

### BACKGROUND

This disclosure relates generally to electric power generation systems. The disclosure more specifically relates to wind and solar powered billboards and fixtures, and methods of using and fabricating the same.

### SUMMARY

Systems and methods for electric power generation are provided. The systems may include a wind turbine electric generator, a fixture, a battery, and a power grid. The wind turbine electric generator may include a wind rotor, a plurality of blades and an electric generator. The wind rotor may be responsive to an air stream and rotatable around a central axis of rotation. The plurality of blades may be mounted to the wind rotor at a radial distance from the central axis of rotation. An image may be displayed on the blades to generate a dynamic image effect with the rotation of the blades around a central axis of rotation. The electric generator may be coupled to and driven by the wind rotor to generate an electrical current. The fixture may be electrically coupled to the wind turbine electric generator to receive a first fraction of the electrical current. The power grid may be electrically coupled to the one wind turbine electric generator to receive a second fraction of the electrical current. The battery may be electrically coupled to the power grid and the wind turbine electric generator to store a third fraction of the electrical current.

In one embodiment, a processor may be coupled to the wind turbine electric generator, the fixture, the battery, and the grid, and configured to transmit a first fraction of the electrical current to the fixture, transmit a second fraction of the electrical current to the battery, and transmit a third fraction of the electrical current to the grid. In another embodiment, an image may be applied to at least two of the plurality of blades to generate a dynamic image effect with the rotation of the plurality of blades around the central axis of rotation. The electric power generation system may include a solar panel for converting light photons to a photo-generated electrical current.

A method for generating electricity to feed a power grid is provided. The method may include providing a wind turbine electric generator with a wind rotor having a plurality of blades, and electrically coupling the wind turbine electric generator to at least one fixture. Next, generating an electrical current using the wind turbine electric generator, transmitting a first fraction of the electrical current from the wind turbine electric generator to the at least one fixture, and powering the at least one fixture using the first fraction of the electrical current. In one embodiment, the method includes transmitting a second fraction of the electrical current to a power grid electrically coupled to the wind turbine electric generator. The method may also include transmitting a third fraction of the electrical current for storage as electrical energy in a battery, and powering the at least one fixture using the electrical energy. In one embodiment, the method may include displaying an image on at least two of the plurality of blades to generate a dynamic image effect with the rotation of the plurality of blades around the central axis of rotation.

Many other features and embodiments of the present invention will be apparent from the accompanying drawings and from the following detailed description.

### BRIEF DESCRIPTION OF THE DRAWINGS

The above-mentioned features and objects of the present disclosure will become more apparent with reference to the following description taken in conjunction with the accompanying drawings wherein like reference numerals denote like elements and in which:

FIG. 1 illustrates an electric power generation system, according to an embodiment of the present disclosure.

FIG. 2 illustrates a wind-powered cell tower, according to an embodiment of the present disclosure.

FIG. 3 illustrates a billboard assembly powered by one or more renewable energy products, according to an embodiment of the present disclosure.

FIG. 4 illustrates an exemplary flowchart outlining a method for generating electricity while calling a consumer's attention to a product or service, according to an embodiment of the present disclosure.

### DETAILED DESCRIPTION

In the description that follows, the present disclosure will be described in reference to one or more embodiments of wind-powered billboards and fixtures, and methods of using and fabricating the same. The present disclosure, however, is not limited to any particular application nor is it limited by the examples described herein. The present disclosure, for example, may be used with any renewable energy product. Therefore, the description of the embodiments that follow are for purposes of illustration and not limitation.

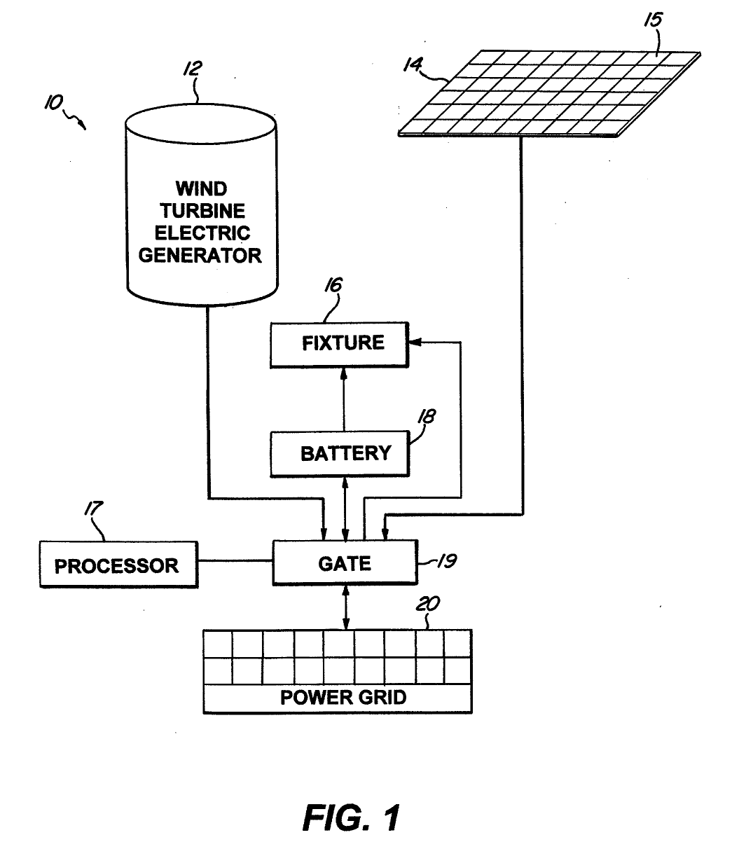

FIG. 1 illustrates an electric power generation system 10, according to an embodiment of the present disclosure. The electric power generation system 10 may include a wind turbine electric generator 12, a solar panel 14, a fixture 16, a processor 17, a battery 18, a gate 19, and a power grid 20.

The wind turbine electric generator 12 may include a wind-driven turbine (not shown) and an electric generator (not shown). The electric generator may be coupled to and driven by the wind turbine to generate electricity. The solar panel 14 may include one or more photovoltaic cells 15 used for converting light photons to photo-generated electrical current. In one embodiment, the solar panel 14 may be electrically coupled to the fixture 16 to provide photo-generated electrical current to power the fixture 16. In another embodiment, the wind turbine electric generator 12 may also be electrically coupled to the fixture 16 to provide wind-generated electricity to power the fixture 16.

The fixture 16 may include, but is not limited to, a billboard, a light fixture, a wireless communications tower, a heating system, a cooling system, a building, a water irrigation system, and an oil rig. In one embodiment, the fixture 16 may receive a first fraction of the electrical current generated by the wind turbine electric generator 12 and the remainder from the electrical current generated by the solar panel 14.

The power grid 20 may be electrically coupled to the wind turbine electric generator 12, the solar panel 14 and/or the battery 18 to receive a second fraction of the electrical current generated therefrom. The power grid 20 may also be electrically coupled to the battery 18 to transmit electrical current to the battery 18. Additionally, the battery 18 may be electrically coupled to the wind turbine electric generator 12 and/or the solar panel 14 to store a third fraction of the electrical current generated therefrom. The second and third fractions may be the excess electrical current unconsumed by the fixture 16.

When there is insufficient electrical current generated by the wind turbine electric generator 12 and/or the solar panel 14 to power the fixture 16 and to store the excess in the battery 18, the battery 18 may be charged up from the power grid 20 by transferring electrical current from the power grid 20 to the battery 18. Alternatively, when there is a surplus of electrical current generated by the wind turbine electric generator 12 and/or the solar panel 14 to power the fixture 16 and to store the excess in the battery 18, the battery 18 may be used to discharge electrical current to the power grid 20.

As can be appreciated, a module (not shown) may be used to control the operation of gate 19. Gate 19, may be any gate, such as a transistor gate, used by artisans to control the flow of electrical current. In one embodiment, the processor 17 may be used (to implement the module) or configured to (1) transmit a fraction of the electrical current to and from the battery 18, (2) transmit a fraction of the electrical current to the power grid 20 from the wind turbine electric generator 12, the solar panel 14 and/or the battery 18, and (3) transmit a fraction of the electrical current to the fixture 16.

As used herein, the term module refers to logic implemented in hardware and/or software. It may include a collection of software instructions, possibly having entry and exit points, written in a programming language, such as, for example, C++. A software module may be compiled and linked into an executable program, or installed in a dynamic link library, or may be written in an interpretive language such as BASIC. It will be appreciated that software modules may be callable from other modules, and/or may be invoked in response to detected events or interrupts. Software instructions may be embedded in firmware, such as an EPROM. It will be further appreciated that hardware modules may be comprised of connected logic units, such as gates and flip-flops, and/or may be comprised of programmable units, such as programmable gate arrays. The modules described herein are preferably implemented as software modules, but could be represented in hardware or firmware.

In one embodiment, each module is provided as a modular code object, where the code objects typically interact through a set of standardized function calls. In one embodiment, the code objects are written in a suitable software language such as C++, but the code objects can be written in any low level or high level language. In one embodiment, the code modules are implemented in C++ and compiled on a computer running a content server, such as, for example, Microsoft® IIS or Linux® Apache. Alternatively, the code modules can be compiled with their own front end on a kiosk, or can be compiled on a cluster of server machines and transmitted through a cable, packet, telephone, satellite, or other telecommunications network. Artisans of skill in the art will recognize that any number of implementations, including code implementations directly to hardware, are also possible.

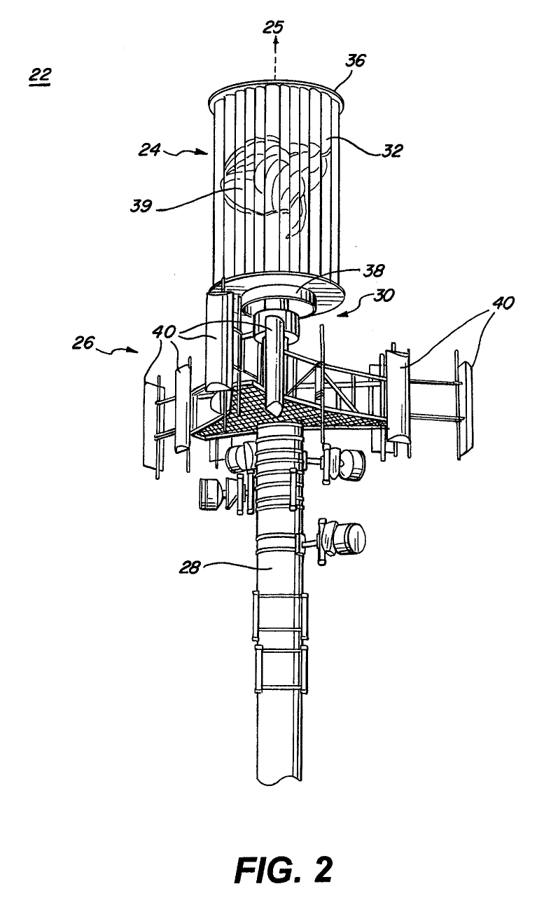

FIG. 2 illustrates a wind-powered cell tower 22, according to an embodiment of the present disclosure. The wind-powered cell tower 22 may include a wind turbine 24, a communication system 26 and a support structure 28. The wind turbine 24 may have any configuration or alignment. As shown in FIG. 2, the wind turbine 24 may have a vertical axis 25. In another embodiment, wind turbine 24 may have a horizontal axis.

As can be appreciated, the wind turbine 24 may include a wind rotor 30 and a plurality of blades 32. The wind rotor 30 may have a lower plate 34 and an upper plate 36. The lower plate 34 and the upper plate 36 may be used to support the plurality of blades 32, which are connected to and extending axially between the plates 34, 36. The blades 32 may be aligned at a radial distance from a central axis of rotation 25. The driving force for this wind rotor 30 is the interaction of the blades 32 with an air stream. The blades 32 may all have an angular orientation around their own axis relative to the plates 34, 36.

The cross sectional shape of the blades 32 is arbitrary and may be made with a variety of shapes. In one embodiment, each blade 32 has about a 30 degree arc relative to a nominal attack axis of the wind to derive a desired net “lifting” force. The blades 32 may be set at any angle relative to their respective radius such that the blades 32 are properly aligned to exert the most effective force on the plates 34, 36 within its most effective angle of attack. The blades 32 may be made from reinforced foam, fiber reinforced extrusions, or metal skins as desired. Lightweight plastic foams with a dip coated skin may also be used.

In one embodiment, the wind rotor 30 may be coupled to an electric generator 38. The wind rotor 30 may be used to drive the electric generator 38 to generate an electrical current. As will be discussed in detail below, the generated electrical current may be used to display an image 39 on at least two of the blades 32 to generate a static or dynamic image effect with the rotation of the blades 32 around the central axis of rotation. The generated electrical current may also be used to provide power to the communication system 26.

As discussed above, the electric generator of the wind turbine may be electrically coupled to a power grid. When there is insufficient electrical current generated by the wind turbine electric generator 38 to power the communication system 26, the power grid may be used to feed the communication system 26 and/or charge up a battery (not shown) that is electrically coupled to and feeds power to the communication system 26. Alternatively, when there is a surplus of electrical current generated by the wind turbine electric generator 38 to power the communication system 26 and to store the excess in the battery, the battery and/or the wind turbine electric generator 38 may be used to discharge electrical current directly or indirectly to the power grid.

The communication system 26 may include at least one antenna 40, a transceiver (not shown), signal processors (not shown), among others. The at least one antenna 40 may be electrically coupled to the transceiver for transmitting to and receiving data from remote devices, such as but not limited to cell phones and other wireless devices. In one embodiment, the data may be transmitted in the form of electromagnetic waves. As can be appreciated, other forms of communication may be used and implemented using the communication system 26.

A support structure 28, such as a tower or pole, may be used to elevate, support and/or position the communication system 26. The height of the support structure 28 may be increased to a desired dimension to improve the broadcasting capabilities of the communication system 26. Since wind speed increases with increasing height above ground, the desired height dimension of the support structure 28 will also drive the wind turbine 24 to rotate and generate electricity at greater wind speeds.

In one embodiment, the wind-powered cell tower 22 may have an image 39 displayed on at least two of the blades 32 to generate a static or dynamic image effect with the rotation of the blades 32 around the central axis of rotation. The image 39 may be displayed on one or more coaxially aligned blades as described in U.S. patent application Ser. No. 12/483,581, filed Jun. 12, 2009, the contents of which are incorporated by reference herein in its entirety.

To generate a dynamic image effect, images 39 may be applied in a predetermined pattern on the blades 32, for each image frame, to appear dynamic with the display of each image frame, in sequence, via the rotation of the blades 32. Alternatively, to generate a dynamic image effect, one or more blades 32 may each display an image frame with image 39 in a predetermined pattern to appear dynamic with the display of each image frame, in sequence, via the rotation of the blades 32. The predetermined pattern may be a slight change in the shape of the image from the image displayed in the prior and/or post image frame, such that with the rotation of the turbine, a dynamic image effect appears to the naked eye.

As can be appreciated, the appearance of a dynamic image may be used to catch the attention of nearby individuals. Various colors, designs, and inks may be used for the image 39. In one embodiment, the image 39 may include an advertisement and/or a pattern for calling a consumer's attention to a product or service, for example, a company logo or a product image.

The image 39 can be displayed on one or more blades 32 by printing, imprinting, typing or coupling the image 39 onto the one or more blades. Other methods known to a person skilled in the art may also be used to display and/or apply the image 39 on the one or more blades. For example, the image 39 may be coupled by means of an adhesive or other attachment means known to a person skilled in the art. In one embodiment, the image 39 may be displayed on the one or more blades 32 by projecting a light projection beam (not shown) of the image 39 from a projector. In another embodiment, the image 39 may be displayed on the one or more blades 32 using an array of light sources (not shown) coupled to the one or more blades 32. For example, an array of light bulbs (not shown) may be coupled to the wind rotor 30 and/or the blades 32. The light bulbs may be triggered to light at a certain time and/or location as the wind turbine 24 rotates around the central axis of rotation. For example, the light bulbs may be triggered to light on and off using a programmable chip (not shown) or a machine-readable medium with code instructions, which when read by a processor, may cause the light bulbs to turn on or off. The processor may be coupled to the light bulbs to control the on and off switching. Alternatively, the processor may wirelessly transmit to a receiver or transceiver (not shown), coupled to the light bulbs, to control the on and off switching.

By selectively turning some light bulbs on while others are turned off, an image 39 may be displayed on the blades 32. The image 39 may appear dynamic as the blades 32 rotates, or static, despite the rotation of the blades 32, for example, by programming the light bulbs to sequentially turn on and off at the same speed at which the wind turbine 24 rotates. As is understood by persons skilled in the art, other light sources for displaying the image may be used, for example, but not limited to, LCD display panels and plasma display panels.

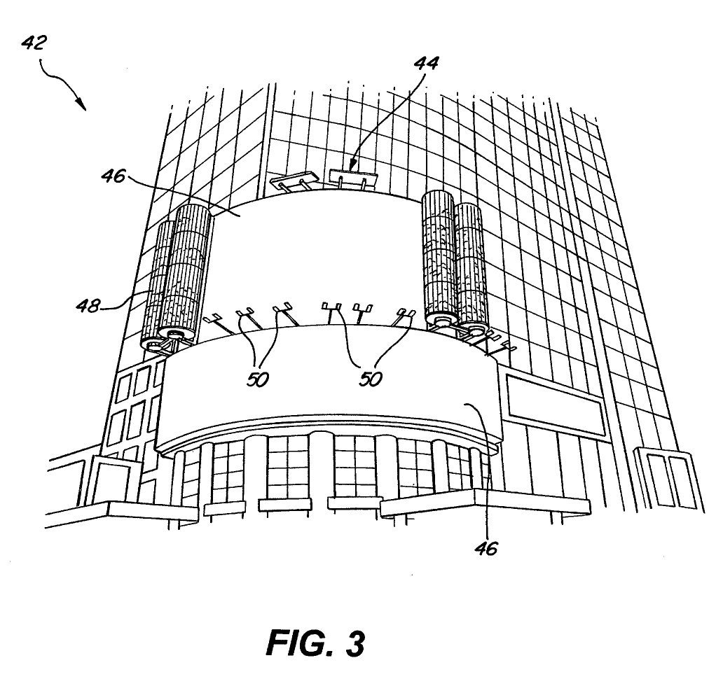

FIG. 3 illustrates a billboard assembly 42 powered by one or more renewable energy products, according to an embodiment of the present disclosure. The billboard assembly 42 may include at least one solar panel 44, a billboard 46, at least one wind turbine electric generator 48, at least one light source 50, and a battery (not shown).

As is well known to persons skilled in the art, the billboard 46 may be an electronic billboard that comprise an array of light sources (not shown), such as LED lights, LCD screens or plasma screens, configured to display an image, such as an advertisement, on the billboard 46. Alternatively, the billboard 46 may be a poster, sign or banner that can be viewed at night using at least one light source 50.

As described above, an image may be displayed on one or more blades of the wind turbine to generate a static or dynamic image effect with the rotation of the blades around a central axis of rotation. The image may include a pattern or advertisement for calling a consumer's attention to a product or service. For example, the image on the turbine blades may have a color pattern that calls the consumer's attention to the wind turbine 48 and the adjacent billboard 46.

In one embodiment, the billboard 46 and/or the light source(s) 50 may be powered by electricity generated from the at least one wind turbine electric generator 48. The at least one wind turbine electric generator 48 may be positioned adjacent the billboard 46. In one embodiment, the billboard 46 and/or the light source(s) 50 may also be powered by photo-generated electrical current generated from the at least one solar panel 44. As can be appreciated, by powering the billboard 44 and/or the light source(s) 50 with the at least one wind turbine electric generator 48 and/or the at least one solar panel 44, significant energy costs can be saved.

As illustrated in FIG. 1, the fixture 16 is electrically coupled to the wind turbine electric generator 12, the solar panel 14, the battery 18 and the power grid 20. Similarly, the billboard 46 and/or the light source(s) 50 may be electrically coupled to the wind turbine electric generator 48, the solar panel 44, the battery (not shown) and the power grid (not shown). When there is insufficient electrical current generated by the wind turbine electric generator 48 and/or the solar panel 44 to power the billboard 46 and/or the light source(s) 50, the battery may be used to feed electrical current to the billboard 46 and/or the light source(s) 50. If the battery is not charged up, the power grid may be used to feed electrical current to the billboard 46 and/or the light source(s) 50, and/or charge up the battery. Alternatively, when there is a surplus of electrical current generated by the wind turbine electric generator 48 to power the billboard 46 and/or the light source(s) 50 and to store the excess in the battery, the battery, the wind turbine electric generator 48 and/or the solar panel 44 may be used to discharge electrical current directly or indirectly to the power grid.

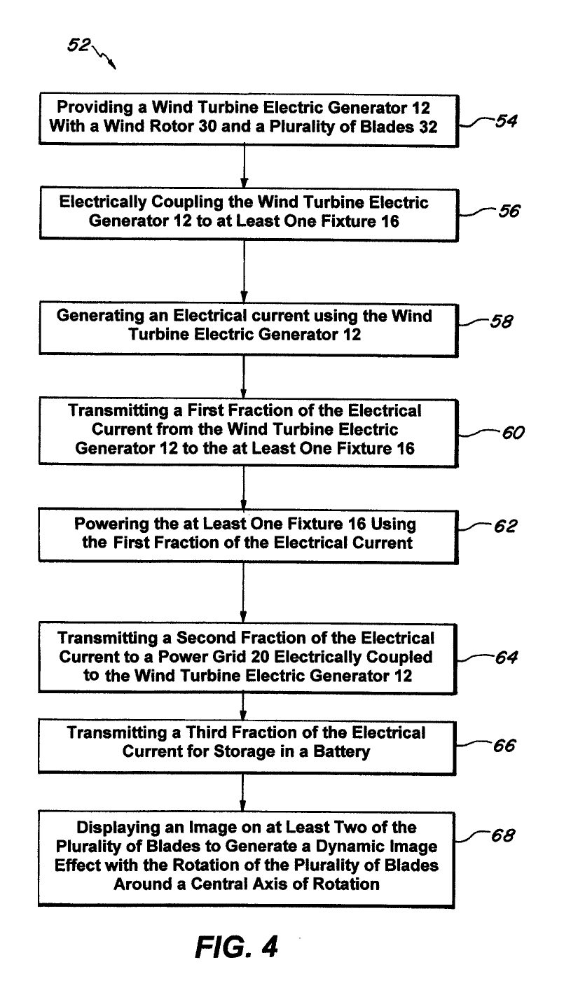

FIG. 4 illustrates an exemplary flowchart 52 outlining a method for generating electricity while calling a consumer's attention to a product or service, according to an embodiment of the present disclosure. The method may include providing a wind turbine electric generator 12 with wind rotor 30 and plurality of blades 32 (54). The wind rotor 30 being responsive to an air stream and rotatable around a central axis of rotation 25. The plurality of blades 32 being mounted to the wind rotor 30 at a radial distance from the central axis of rotation 25. In one embodiment, the wind turbine electric generator 12 may be electrically coupled to at least one fixture 16 (56). The wind turbine electric generator 12 may then be used to generate an electrical current (58), for which a first fraction of the electrical current may be transmitted to the at least one fixture 16 (60) to power the at least one fixture 16 (62). In one embodiment, a second fraction of the electrical current may be transmitted to a power grid 20 electrically coupled to the wind turbine electric generator 12 (64). In another embodiment, a third fraction of the electrical current may be transmitted to battery 18 for storage (66).

As can be appreciated, an image may be displayed on at least two of the plurality of blades 32 to generate a dynamic image effect with the rotation of the plurality of blades 32 around the central axis of rotation 25 (68). The image may be displayed on the blades 32 using methods known to persons skilled in the art, including but not limited to, printing, imprinting, typing, coupling the image onto the one or more blades 32. The image may also be displayed on the one or more blades 32 by projecting a light projection beam of the image or by, for example, selectively switching on and off an array of light bulbs coupled to the blades 32.

As can be appreciated by a person skilled in the art, the wind turbine may not only generate revenue by producing electricity from wind, but also generate revenue from advertising space available on the blades of the wind turbine.

The embodiments of the present disclosure are not limited to wind turbine electric generation systems or wind turbines but can also be used with any other renewable energy product. For example, solar panels (e.g. as shown in FIG. 1 and FIG. 3) may also have an advertisement or image applied to the surface of the panel. A static or dynamic image of, for example, an advertisement, may be translucent or transparent to allow light to pass through the solar panels. The light may then be captured and converted to electricity by photovoltaic effect. As can be appreciated by a person skilled in the art, the solar panels may not only generate revenue by producing electricity from light, but also generate revenue from advertising space available on the outer surface of the solar panels.

In this description, various functions and operations may be described as being performed by or caused by software code to simplify description. However, those skilled in the art will recognize that what is meant by such expressions is that the functions result from execution of the code/instructions by a processor, such as a microprocessor. Alternatively, or in combination, the functions and operations can be implemented using special purpose circuitry, with or without software instructions, such as using Application-Specific Integrated Circuit (ASIC) or Field-Programmable Gate Array (FPGA). Embodiments can be implemented using hardwired circuitry without software instructions, or in combination with software instructions. Thus, the techniques are limited neither to any specific combination of hardware circuitry and software, nor to any particular source for the instructions executed by the data processing system. While some embodiments can be implemented in fully functioning computers and computer systems, various embodiments are capable of being distributed as a computing product in a variety of forms and are capable of being applied regardless of the particular type of machine or computer-readable media used to actually effect the distribution.

At least some aspects disclosed can be embodied, at least in part, in software. That is, the techniques may be carried out in a computer system or other data processing system in response to its processor, such as a microprocessor, executing sequences of instructions contained in a memory, such as ROM, volatile RAM, non-volatile memory, cache or a remote storage device.

Routines executed to implement the embodiments may be implemented as part of an operating system or a specific application, component, program, object, module or sequence of instructions referred to as “computer programs.” The computer programs typically include one or more instructions set at various times in various memory and storage devices in a computer, and that, when read and executed by one or more processors in a computer, cause the computer to perform operations necessary to execute elements involving the various aspects.

A machine readable medium can be used to store software and data which when executed by a data processing system causes the system to perform various methods. The executable software and data may be stored in various places including for example ROM, volatile RAM, non-volatile memory and/or cache. Portions of this software and/or data may be stored in any one of these storage devices. Further, the data and instructions can be obtained from centralized servers or peer to peer networks. Different portions of the data and instructions can be obtained from different centralized servers and/or peer to peer networks at different times and in different communication sessions or in a same communication session. The data and instructions can be obtained in entirety prior to the execution of the applications. Alternatively, portions of the data and instructions can be obtained dynamically, just in time, when needed for execution. Thus, it is not required that the data and instructions be on a machine readable medium in entirety at a particular instance of time. Examples of computer-readable media include but are not limited to recordable and non-recordable type media such as volatile and non-volatile memory devices, read only memory (ROM), random access memory (RAM), flash memory devices, floppy and other removable disks, magnetic disk storage media, optical storage media (e.g., Compact Disk Read-Only Memory (CD ROMS), Digital Versatile Disks (DVDs), etc.), among others.

The computer-readable media may store the instructions. In general, a tangible machine readable medium includes any mechanism that provides (i.e., stores and/or transmits) information in a form accessible by a machine (e.g., a computer, network device, personal digital assistant, manufacturing tool, any device with a set of one or more processors, etc.).

In various embodiments, hardwired circuitry may be used in combination with software instructions to implement the techniques. Thus, the techniques are neither limited to any specific combination of hardware circuitry and software nor to any particular source for the instructions executed by the data processing system. Although some of the drawings illustrate a number of operations in a particular order, operations which are not order dependent may be reordered and other operations may be combined or broken out. While some reordering or other groupings are specifically mentioned, others will be apparent to those of ordinary skill in the art and so do not present an exhaustive list of alternatives. Moreover, it should be recognized that the stages could be implemented in hardware, firmware, software or any combination thereof.

The disclosure includes methods and apparatuses which perform these methods, including data processing systems which perform these methods, and computer readable media containing instructions which when executed on data processing systems cause the systems to perform these methods.

While the methods and systems have been described in terms of what are presently considered to be the most practical and preferred embodiments, it is to be understood that the disclosure need not be limited to the disclosed embodiments. It is intended to cover various modifications and similar arrangements included within the spirit and scope of the claims, the scope of which should be accorded the broadest interpretation so as to encompass all such modifications and similar structures. The present disclosure includes any and all embodiments of the following claims.

It should also be understood that a variety of changes may be made without departing from the essence of the invention. Such changes are also implicitly included in the description. They still fall within the scope of this invention. It should be understood that this disclosure is intended to yield a patent covering numerous aspects of the invention both independently and as an overall system and in both method and apparatus modes.

Further, each of the various elements of the invention and claims may also be achieved in a variety of manners. This disclosure should be understood to encompass each such variation, be it a variation of an embodiment of any apparatus embodiment, a method or process embodiment, or even merely a variation of any element of these.

Particularly, it should be understood that as the disclosure relates to elements of the invention, the words for each element may be expressed by equivalent apparatus terms or method terms—even if only the function or result is the same.

Such equivalent, broader, or even more generic terms should be considered to be encompassed in the description of each element or action. Such terms can be substituted where desired to make explicit the implicitly broad coverage to which this invention is entitled.

It should be understood that all actions may be expressed as a means for taking that action or as an element which causes that action.

Similarly, each physical element disclosed should be understood to encompass a disclosure of the action which that physical element facilitates.

In this regard it should be understood that for practical reasons and so as to avoid adding potentially hundreds of claims, the applicant has presented claims with initial dependencies only.

To the extent that insubstantial substitutes are made, to the extent that the applicant did not in fact draft any claim so as to literally encompass any particular embodiment, and to the extent otherwise applicable, the applicant should not be understood to have in any way intended to or actually relinquished such coverage as the applicant simply may not have been able to anticipate all eventualities; one skilled in the art, should not be reasonably expected to have drafted a claim that would have literally encompassed such alternative embodiments.

Further, the use of the transitional phrase “comprising” is used to maintain the “open-end” claims herein, according to traditional claim interpretation. Thus, unless the context requires otherwise, it should be understood that the term “compromise” or variations such as “comprises” or “comprising”, are intended to imply the inclusion of a stated element or step or group of elements or steps but not the exclusion of any other element or step or group of elements or steps.

Such terms should be interpreted in their most expansive forms so as to afford the applicant the broadest coverage legally permissible.

1. An electric power generation system, comprising:
at least one wind turbine electric generator, having:
a wind rotor responsive to an air stream and rotatable around a central axis of rotation, and
a plurality of blades mounted to the wind rotor at a radial distance from the central axis of rotation;
an image displayed on at least two of the plurality of blades to generate a dynamic image effect with the rotation of the plurality of blades around the central axis of rotation; and
an electric generator coupled to and driven by the wind rotor to generate an electrical current;
at least one fixture electrically coupled to the at least one wind turbine electric generator to receive a first fraction of the electrical current; and
a power grid electrically coupled to the at least one wind turbine electric generator to receive a second fraction of the electrical current.

2. The electric power generation system of claim 1, further comprising a solar panel for converting light photons to a photo-generated electrical current, the solar panel being electrically coupled to the at least one fixture to provide the photo-generated electrical current to the at least one fixture.

3. The electric power generation system of claim 1, wherein the at least one fixture comprises: at least one billboard, at least one light fixture, at least one wireless communications tower, at least one heating system, at least one cooling system, at least one building, at least one water irrigation system, and at least one oil rig.

4. The electric power generation system of claim 1, further comprising at least one battery, electrically coupled to the power grid and the at least one wind turbine electric generator, for storing a third fraction of the electrical current.

5. The electric power generation system of claim 1, wherein the image is applied across two or more of the plurality of blades by attachment means.

6. The electric power generation system of claim 1, wherein the image is applied across two or more of the plurality of blades by projecting a light projection beam thereon.

7. The electric power generation system of claim 1, wherein the image comprises a pattern for calling a consumer's attention to a product or service.

8. A renewable energy system for generating electricity, comprising:
at least one wind turbine electric generator, having:
a wind rotor responsive to an air stream and rotatable around a central axis of rotation;
a plurality of blades mounted to the wind rotor at a radial distance from the central axis of rotation, each blade having an outer surface;
at least two images displayed across the outer surface of at least two of the plurality of blades to generate a dynamic image effect with the rotation of the plurality of blades around the central axis of rotation;
an electric generator coupled to and driven by the wind rotor to generate an electrical current;
at least one fixture electrically coupled to the at least one wind turbine electric generator to receive a first fraction of the electrical current;
at least one battery electrically coupled to the at least one wind turbine electric generator to store a second fraction of the electrical current; and
a processor coupled to the at least one wind turbine electric generator, the at least one fixture, and the at least one battery, and configured to transmit the first fraction of the electrical current from the at least one wind turbine electric generator to the at least one fixture and to transmit the second fraction of the electrical current from at least one wind turbine electric generator to the at least one battery.

9. The renewable energy system of claim 8, further comprising a solar panel for converting light photons to a photo-generated electrical current, the solar panel being electrically coupled to the at least one fixture to provide the photo-generated electrical current to the at least one fixture.

10. The renewable energy system of claim 8, wherein the at least one fixture comprises: at least one billboard, at least one light, at least one communications tower, at least one cell-phone tower, at least one heating system, at least one cooling system, at least one building, at least one water irrigation system, and at least one oil rig.

11. The renewable energy system of claim 8, further comprising a power grid, electrically coupled to the at least one battery, the at least one wind turbine electric generator, and the processor for receiving a third fraction of the electrical current.

12. The renewable energy system of claim 8, wherein each image is applied across the outer surface of at least two of the plurality of blades by attachment means.

13. The renewable energy system of claim 8, wherein each image is applied across the outer surface of at least two of the plurality of blades by projecting a light projection beam thereon.

14. A method for generating electricity to feed a power grid, the method comprising:
providing a wind turbine electric generator with a wind rotor having a plurality of blades, the wind rotor being responsive to an air stream and rotatable around a central axis of rotation, the plurality of blades being mounted to the wind rotor at a radial distance from the central axis of rotation;
electrically coupling the wind turbine electric generator to at least one fixture;
generating an electrical current using the wind turbine electric generator;
transmitting a first fraction of the electrical current from the wind turbine electric generator to the at least one fixture;
powering the at least one fixture using the first fraction of the electrical current; and
transmitting a second fraction of the electrical current to a power grid electrically coupled to the wind turbine electric generator.

15. The method of claim 14, further comprising:
transmitting a third fraction of the electrical current for storage as electrical energy in a battery; and
powering the at least one fixture using the electrical energy.

16. The method of claim 14, further comprising:
converting light photons to a photo-generated electrical current with a solar panel, the solar panel being electrically coupled to the at least one fixture; and
powering the at least one fixture using the photo-generated electrical current.

17. The method of claim 14, wherein the at least one fixture comprises: at least one billboard, at least one light, at least one communications tower, at least one cell-phone tower, at least one heating system, at least one cooling system, at least one building, at least one water irrigation system, and at least one oil rig.

18. The method of claim 14, further comprising:
displaying an image on at least two of the plurality of blades to generate a dynamic image effect with the rotation of the plurality of blades around the central axis of rotation.

19. The method of claim 18, further comprising applying the image across two or more of the plurality of blades.

20. The method of claim 18, wherein displaying an image on at least two of the plurality of blades comprises coupling a printed advertisement poster to at least one outer surface of at least two of the plurality of blades.

21. The method of claim 18, wherein displaying an image on at least two of the plurality of blades comprises projecting a light projection beam thereon.

22. A method for generating electricity while calling a consumer's attention to a product or service, the method comprising:
providing a wind turbine electric generator with a wind rotor having a plurality of blades, the wind rotor being responsive to an air stream and rotatable around a central axis of rotation, the plurality of blades being mounted to the wind rotor at a radial distance from the central axis of rotation;
electrically coupling the wind turbine electric generator to at least one fixture;
generating an electrical current using the wind turbine electric generator;
transmitting a fraction of the electrical current from the wind turbine electric generator to the at least one fixture;
powering the at least one fixture using the fraction of the electrical current; and
displaying an image on at least two of the plurality of blades to generate a dynamic image effect with the rotation of the plurality of blades around the central axis of rotation.
